(19) United States
(12) Patent Application Publication
(10) Pub. No.: US 2026/0213755 A1
(43) Pub. Date: Jul. 23, 2026

(54) PHASE LOCK DETECTOR

(71) Applicant: NOVELDA AS, KVITESEID (NO)

(72) Inventor: Lieuwe LEENE, Trondheim (NO)

(73) Assignee: Vitalthings UWB AS, Trondheim (NO)

(21) Appl. No.: 19/140,995

(22) PCT Filed: Dec. 19, 2023
(86) PCT No.: PCT/EP2023/086746

§ 371 Date: Jun. 18, 2025

(30) Foreign Application Priority Data
Dec. 22, 2022 (GB) 2219593.7

(51) Int. Cl. H03L 7/091; H03L 7/095

(52) U.S. Cl. CPC H03L 7/091; H03L 7/095

(57) ABSTRACT

A system for determining whether a first clock signal and a second clock signal are in phase. The system comprises a first latch, arranged to receive the first clock signal and a second latch, arranged to receive the second clock signal. A second detector receives the first and second clock signals. The first latch is arranged to latch when the first clock signal transitions from a first state to a second state. The second latch is arranged to latch when the second clock signal transitions from a first state to a second state. A first detector outputs a first output signal when the first latch and the second latch are latched. The second detector generates a second output signal upon receiving the first output signal, the second output signal being indicative of whether both the first clock signal and the second clock signal are in the second state.

### BACKGROUND OF THE INVENTION

This invention relates to a system and method for detecting lock in a phase locked loop (PLL) control system.

Detection of lock in a phase locked loop typically relies on comparing the output of a phase detector or loop filter of the PLL with a reference input signal. As the output of a phase detector or loop filter encodes phase error in the control loop, comparison with the reference signal may reveal whether the output signal meets a required condition, e.g. whether its variability within a reference clock period is below a threshold value. If the variability of the output signal relative to the input is sufficiently low, it can be inferred that the PLL is in a locked state.

The present invention seeks to provide an improved system for detecting lock in a phase locked loop.

### SUMMARY OF THE INVENTION

According to a first aspect, the invention provides a system for determining whether a first clock signal and a second clock signal are in phase; the system comprising:
a first latch, arranged to receive the first clock signal;
a second latch, arranged to receive the second clock signal;
a first detector; and
a second detector, arranged to receive the first clock signal and the second clock signal;
wherein the first latch is arranged to latch when the first clock signal transitions from a first state to a second state;
wherein the second latch is arranged to latch when the second clock signal transitions from a first state to a second state;
wherein the first detector is configured to output a first detector output signal when the first latch and the second latch are latched; and
wherein the second detector is arranged to generate a second detector output signal upon receiving the first detector output signal, the second detector output signal being indicative of whether both the first clock signal and the second clock signal are in the second state.

According to a second aspect the invention provides a method of determining whether a first clock signal and a second clock signal are in phase; the method comprising:
detecting a change of state of a first one of the first and second clock signals at a first time,
detecting a change of state of a second one of the first and second clock signals at a second time,
in response to detecting the change of state of the second one of the first and second clock signals at the second time, comparing the state of the first and second clock signals at the second time; and
determining that the first and second clock signals are in phase based on the first and second clock signals being in the same state at the second time.

Thus it will be seen that, in accordance with this disclosure there is provided a system and method for determining whether two clock signals are phase, in which the proximity of the edges of a first clock signal (e.g. a reference clock) and a second clock signal (e.g. a generated clock signal) in the time domain is assessed to determine whether the two signals are in phase. This is achieved by determining firstly, that the first and second clock signals have entered the same state (e.g. logic high or logic low), and secondly, that, at the time the second clock signal enters the same state as the first clock signal, both the first clock signal and the second clock signal remain in the same state. Essentially, this arrangement determines if the two clock signals are sufficiently close in phase based on the overlap between them. If the two clock signals are not in phase then they will drift until one clock changes state twice before the other clock catches up. This will result in a detection of non overlap which can then be used to determine a degree of lock. This is a particularly efficient design with a low number of components that can operate fast and can thus operate reliably on very high speed clocks.

In some embodiments, the first detector output signal may be received by the first latch and the second latch, causing the first latch and the second latch to reset. The first latch and the second latch may have a reset input arranged to receive the first detector output signal. This allows the first latch and the second latch to be reset quickly after both latches have latched, such that they are returned to their initial (e.g. unlatched or reset) state ready to act on the next changes of state in their respective clock signals. This allows a plurality of changes of state of the first and second clock signals to be detected in quick succession. As soon as a transition has been detected on both clock signals, the overlap is checked and the latches can be reset for the next check.

In some embodiments, the first latch and the second latch may be bi-stable, i.e. they have two stable states. For example they may be latched or unlatched or they may be in either a set state or a reset state. In such embodiments, resetting the first latch and the second latch may cause the first latch and the second latch to become unlatched or to be put into the reset state. In the unlatched or reset state, the first latch and the second latch may be effectively reset, such that they are able to receive further inputs from the first clock and the second clock respectively.

The term “latch” in this document is used in a broad sense to cover bi-stable circuits that have a set state (latched state) and a reset state (unlatched state), i.e. it covers both edge-triggered and level-triggered latches. It is likewise used to cover both simple (sometimes referred to as transparent or asynchronous) latches and flip flops (sometimes referred to as synchronous or clocked latches).

In some embodiments, the first latch may comprise a first resettable D flip flop (sometimes referred to as a delay or data flip flop), the second latch may comprise a second resettable D flip flop, and the first resettable D flip flop and the second resettable D flip flop each comprise a respective clocking input and a reset input.

The first clock signal may be received at the clocking input of the first latch, and the second clock signal may be received at the clocking input of the second latch. In this way the timing of the latching of the first resettable D flip flop and the second resettable D flip flop is controlled by the first and second clock signals respectively. It will be appreciated that the clocking inputs of the first and second latch may be arranged to trigger the latch on a rising edge received at the clocking input or on a falling edge received at the clocking input. Each of the first and second latches may be arranged to latch (i.e. to enter the latched state or set state) upon receiving the appropriate signal (e.g. rising edge or falling edge) at the clocking input. Once latched, each latch will remain in the latched (or set) state until it is reset by an appropriate signal at its reset input. The reset input of the first and second latches may be arranged to receive the first detector output signal. Thus each latch is arranged to be driven to the latched (or set) state upon receipt of its respective clocking signal and to be driven to the unlatched (or reset) state upon receipt of the reset signal which indicates that both latches are in the latched (or set) state.

In some embodiments, the first clock signal may be provided to the clocking input of the first resettable D flip flop and the second clock signal may be provided to the clocking input of the second resettable D flip flop. In some embodiments, the reset input of the first resettable D flip flop and the reset input of the second resettable D flip flop may be configured to receive the first detector output signal. The first D flip flop and the second D flip flop may also have a third ‘data’ input. The data input may be configured to receive a stable (e.g. fixed) predetermined input, such as a fixed high signal. This data input is used to drive the latches to the latched or set state when an appropriate input is received at the clocking input.

In some embodiments, the first latch may be configured to detect the change of state of the first clock signal based on the first clock signal transitioning from the first state to the second state. Similarly, in some embodiments, the second latch may be configured to detect the change of state of the second clock signal based on the second clock signal transitioning from the first state to the second state. This allows the first latch and the second latch to detect changes in state of the first and second clock signals respectively. Based on the change of state of the first and/or second clock signals, one or more outputs of the first latch and/or the second latch may change. For example, the first latch may provide an output signal indicative of the current state of the first latch (whether it is latched or unlatched, or in other words whether it is set or reset). When the first latch is in the unlatched state and when the state of the first clock signal transitions from the first state to the second state, the first latch will transition from the unlatched state to the latched state and the output of the first latch will change, representing detection of the change of state of the first clock signal. For example, the first latch output may switch from high to low or vice versa. Similarly, the second latch may provide an output signal indicative of the current state of the second latch (whether it is latched or unlatched, or in other words whether it is set or reset). When the second latch is in the unlatched state and when the state of the second clock signal transitions from the first state to the second state, the second latch will transition from the unlatched state to the latched state and the output of the second latch will change, representing detection of the change of state of the second clock signal. For example, the second latch output may switch from high to low or vice versa.

It will be appreciated that some latches may have multiple outputs. For example, each latch may also output an inverted form of the output signal for convenience.

In some embodiments, the first clock signal and/or the second clock signal may be a square wave signal. The square wave signal may have two states, e.g. high (such as a digital 1) and low (such as a digital 0). In some embodiments, the first state of the first and/or second clock signals may correspond to a high state of the square wave, and the second state of the first and/or second clock signals may correspond to a low state of the square wave. However, it will be appreciated that in some embodiments, the first state of the first and/or second clock signals may correspond to a low state of the square wave and the second state of the first and/or second clock signals may correspond to a high state of the square wave. The transition between the low state and the high state may be used to define a rising edge of the first and/or second clock signals, and the transition between the high state and the low state may be used to define a falling edge of the first and/or second clock signals.

In some embodiments, the first detector may comprise a first logic gate. For example, the first detector may be a first AND gate. Using an AND gate as the first detector provides a means for generating the first detector output signal (at the output of the AND gate) that indicates whether the first latch and the second latch are both latched (i.e. both in the latched or set state) simultaneously. This signal may be provided to the second detector to cause it to determine whether the first clock signal and the second clock signal are both in the second state (e.g. whether they are in phase) and it may simultaneously be provided to the reset inputs of the latches as discussed above.

In some embodiments, the second detector may be arranged to receive the first clock signal and the second clock signal, and to determine whether the first clock signal and the second clock signal are in the same state. In some embodiments, the second detector may comprise a second logic gate and a third latch. In some such embodiments, the second logic gate may be a second AND gate configured to receive, as inputs, the first clock signal and the second clock signal.

In such embodiments, the second AND gate may be configured to output an overlap signal indicative of whether both the first clock signal and the second clock signal are in the second state. For example, if the inputs received at second AND gate (the first and second clock signals) are simultaneously high (i.e. in embodiments where the second state is high), the second AND gate will provide a high output, indicating that the first clock signal and the second clock signal are in the same high state. If, however, only one of the first and second clock signals is high while the other is low (or if both are low), the second AND gate will provide a low output. The second AND gate may provide its output to the third latch.

It will be appreciated that in other embodiments a different logic gate may be used. For example, in embodiments in which the second state is low, a NOR gate may be used to output a high signal when both the first clock and the second clock are in the low state and to output a low signal in all other cases. For such embodiments, if D flip flops are used as the latches then these would need to have falling-edge sensitivity rather than the rising-edge sensitivity that is used when the second logic gate is an AND gate. It will be appreciated that a combination of logic gates may be used to achieve similar logic. However, it is particularly convenient that only a single logic gate is required here to detect the overlap of the first and second clock signals in the second state. The use of a single gate allows fast operation and a simple detection circuit suitable for high speed operation.

In some embodiments, the third latch may be a D flip flop comprising a clocking input and a data input. The first detector output signal may be provided to the clocking input of the third latch, and the output signal of the second logic gate (e.g. second AND gate) may be provided to the data input of the third latch.

In some embodiments, the system may comprise a lead signal detector, configured to determine the latching order of the first latch and the second latch (i.e. the order in which the first latch and the second latch switch to the set state). In some such embodiments, the lead signal detector may be configured to output an ‘order’ signal having a first state and a second state. The first state of the order signal may indicate that the first clock signal leads the second signal (i.e. the first clock signal is received before the second clock signal), and wherein the second state of the order signal may indicate that the second clock signal leads the first clock signal (i.e. the second clock signal is received before the first clock signal). The use of a lead signal detector may advantageously allow determination of the lead/lag state of the first and second clock signals, e.g. to provide an indication of their relative phases. This information can be used be other circuitry, e.g. control circuitry to correct for the phase difference and maintain lock.

According to a third aspect, a phase locked loop is provided comprising a system for determining whether a first clock signal and a second clock signal are in phase as described above. In some embodiments, the phase locked loop may comprise a counter element, configured to receive the second detector output signal. The counter element may be configured to determine, based on the second detector output signal, whether the phase locked loop is in a locked state. For example, if the second detector output signal remains stable for a predetermined time, e.g. for a predetermined number of clock cycles, the counter may determine that the phase locked loop is in a locked state. In this way the system for determining whether a first clock signal and a second clock signal are in phase can be used to aid determination of phase lock in a phase locked loop. In some embodiments, the phase locked loop may be determined to be in a locked state if the second detector output signal received by the counter element remains constant for a predetermined number of clock cycles. For example, the counter may be arranged to add a count to its total if the second detector output signal is high when the counter receives a clock signal. The counter may be periodically reset to restart the count and get a new measure of phase lock. Alternatively, the counter may be arranged to maintain a rolling count over a certain number of clock cycles. The phase locked loop may then be considered to be in a locked state when the counter value is above a certain threshold. This allows occasional glitches to be ignored while still capturing significant and continued deviations from the locked state when the clock signals get out of an overlap state. In some embodiments the threshold may be set such that only a maximum count is considered to be indicative of a locked state (i.e. a single non-overlapped clock signal may be considered to be indicative of a loss of phase lock).

Features of any aspect or embodiment described herein may, wherever appropriate, be applied to any other aspect or embodiment described herein.

Where reference is made to different embodiments or sets of embodiments, it should be understood that these are not necessarily distinct but may overlap.

### BRIEF DESCRIPTION OF THE DRAWINGS

Certain preferred embodiments of the invention will now be described, by way of example only, with reference to the accompanying drawings, in which:

FIG. 1 is a schematic representation of a digital phase lock loop according to the prior art;

FIG. 2 is a schematic representation of a digital phase lock detection mechanism according to an embodiment of the present invention;

FIG. 3 is a diagram illustrating the signals produced by the principle components of a digital phase lock detection mechanism according to an embodiment of the present invention; and

FIG. 4 is a schematic representation of a digital phase lock loop including a phase lock detection mechanism according to the present invention.

### DETAILED DESCRIPTION

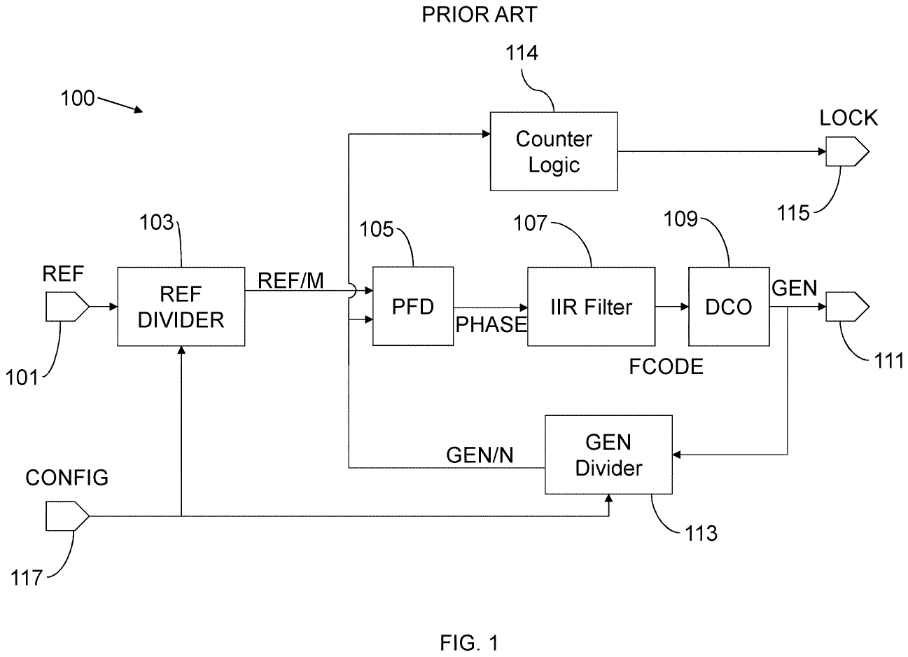

FIG. 1 shows a digital phase locked loop (PLL) 100 according to the prior art. The digital PLL 100 aims to synchronise a generated clock signal GEN with an input reference clock signal REF, such that the two signals are aligned in phase. The prior art digital PLL 100 shown in FIG. 1 aims to use a reference clock signal REF (e.g. generated by a digital oscillator) at a first frequency to generate a clock signal GEN at a second frequency, for example at a higher multiple of the frequency of the reference signal REF while ensuring that the generated signal GEN has the same phase.

The digital PLL 100 shown in FIG. 1 comprises a reference clock source 101 which provides the reference clock signal REF to a first divider 103. The first divider 103 outputs a signal at a lower frequency (REF/M) to a phase frequency detector (PFD) 105 which will be described in the following. The phase frequency detector 105 outputs a phase error value to an Infinite Impulse Response (IIR) filter 107, from which a filtered signal is provided to a digital controlled oscillator (DCO) 109. The DCO 109 outputs the generated clock signal GEN, based on the output of the phase frequency detector 105. The generated clock signal GEN is provided to a second divider 113, as well as to an output 111 of the digital PLL 100.

The second divider 113 outputs a signal at a lower frequency (GEN/N) to the phase frequency detector 105, where it is compared to the output signal of the first divider 103 (i.e. it is compared to the divided reference signal REF/M) to determine the phase error value to be provided to the IIR filter 107. The phase error value determined by the PFD 105 is dependent on the difference in phase between GEN/N and REF/M, which should be zero when the two signals are in phase.

If the frequency of REF/M is higher than GEN/N, the PFD 105 outputs a ‘high’ signal, which, when provided to the digital controlled oscillator 109, is used to increase the frequency of the generated signal GEN output by the DCO 109. If the frequency of REF/M is lower than GEN/N, the PFD 105 outputs a ‘low’ signal, which, when provided to the digital controlled oscillator 109, is used to reduce the frequency of the generated signal GEN. By adjusting the frequency of the generated signal GEN produced by the DCO 109, the generated signal GEN may be brought into phase-alignment with the reference signal REF over time.

To determine whether the generated signal GEN and the reference signal REF are phase-aligned, i.e., whether the digital PLL 100 is in a stable, locked, condition, the GEN Divider 113 also provides the GEN/N output to counter logic 114 which counts the clock cycles of the GEN/N signal over a defined period to obtain a measure of its frequency. The counter logic 114 can thereby determine whether the GEN/N signal is at an expected frequency and/or can determine if the GEN/N frequency is stable. A stable count that does not change much indicates a good lock, whereas a varying count indicates that phase correction is being required. Counter logic 114 outputs a LOCK signal at output 115 if it determines that the GEN and REF signals are sufficiently locked.

In this way, the digital PLL 100 shown in FIG. 1 may be used to generate a clock signal GEN at a frequency set by the ratio M/N, the generated signal GEN being related to the reference clock signal REF such that GEN/N is in phase with REF/M. The digital PLL 100 can also provide an indication of whether phase-lock has been achieved, in the form of the LOCK signal at the output 115. The lock criteria, and the properties of the generated signal (e.g. its frequency relative to that of the reference signal REF), can be set using a configuration input 117, which provides inputs to the first divider 103 and the second divider 113.

However, the arrangement shown in FIG. 1 requires complex circuitry and the frequency-based approach requires a large number of clock cycles to pass before it can determine that the generated signal and the reference signal are in phase (i.e. to determine that the output frequency is in phase and stable relative to the input frequency).

According to at least the preferred embodiments of the invention, phase-lock can advantageously be determined without requiring such complex circuitry by assessing the proximity of edges of the reference clock signal and the generated signal in the time domain rather than in the frequency domain in order to determine a lock condition by implementing a novel lock detection mechanism.

As will be explained in the following, the system of the present invention determines whether the rising (or falling) edges of a reference clock signal and a generated clock signal occur within a time window by making use of ‘latches’ arranged to record whether the two signals have transitioned into the same state (e.g. to record when each of the clock signals becomes logic high). Once it has been determined that the two signals have undergone a transition into this state, the signals are compared to determine whether both the signals remain in that same state at the time at which the second signal enters said state, i.e. whether there is an overlap in the time periods in which the two signals are in the same state.

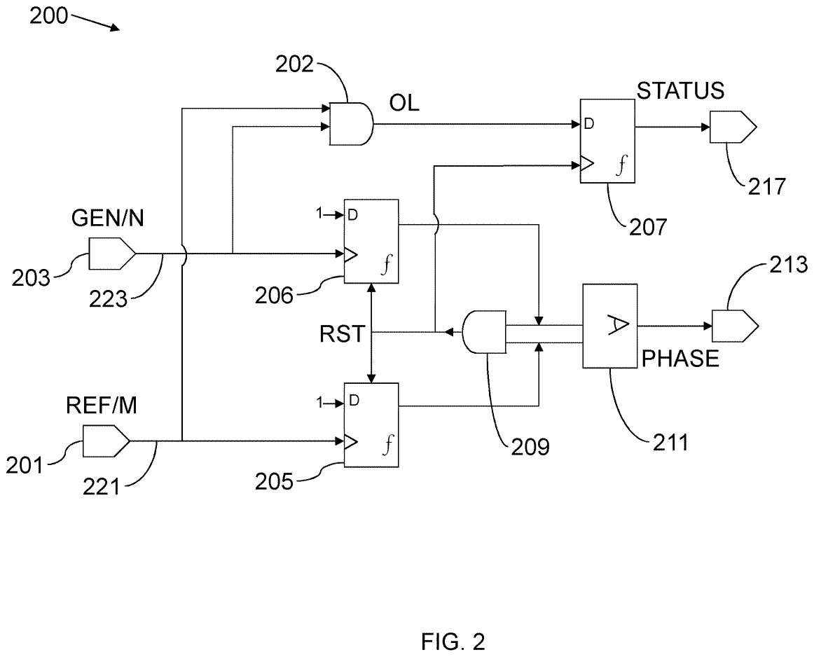

FIG. 2 shows a lock detection mechanism 200 according to an embodiment of the present invention. The lock detection mechanism 200 is arranged to be implemented in a digital phase locked loop to provide an output indicating whether a generated signal and a reference signal are in phase.

The lock detection mechanism 200 comprises a reference clock source 201 which outputs a reference clock signal REF/M 221, and a generated clock source 203 which outputs a generated clock signal GEN/N 223. As described above in relation to the prior art phase locked loop 100, the generated clock signal GEN/N 223 may be a high frequency signal having a frequency which is a multiple of the reference clock signal REF/M 221. For example, the reference clock signal REF/M 221 could be a 1.05 GHZ signal and the generated clock signal GEN/N 223 could have a frequency five times higher than this, i.e., 5.25 GHz. In the embodiments described herein, the reference clock signal REF/M 221 and the generated clock signal GEN/N 223 are square wave signals having two states, a logic high state and a logic low state. The transition between the logic low state and the logic high state occurs at the rising edge of the clock signal, and the transition between the logic high state and the logic low state occurs at the falling edge of the clock signal.

The lock detection mechanism 200 shown in FIG. 2 aims to determine whether the generated clock signal GEN/N 223 and the reference clock signal REF/M 221 are synchronised, and to provide two output signals indicative of their properties-a first output signal (PHASE) indicating whether the two signals are in phase and a second output signal (STATUS) indicating which of the signals leads (or equivalently lags) the other.

In the lock detection mechanism 200, the reference signal REF/M 221 generated by the reference clock source 201 is provided to a first AND gate 202 as well as to the ‘clock’ input of a first latch in the form of a first resettable data flip flop 205, (referred to herein as a D flip flop) having its ‘data’ input initially set to be logic high. The first D flip flop 205 acts as an electronic memory component whose output remains constant until it is triggered by an appropriate clocking input, at which point its output is set to the value of its ‘data’ input. D flip flops are typically edge triggered and thus the output is set upon receipt of an appropriate edge at the clocking input. The D flip flop may be arranged to trigger on a rising edge or a falling edge. The first resettable D flip flop 205 has a constant logic ‘1’ provided at its data input such that an appropriate trigger at its clocking input will result in a ‘1’ at its output. Once the output of the first D flip flop 205 is set in this way, it remains in that state until the first D flip flop 205 is reset. While the rising edge of a clock signal is detected in the embodiment shown in FIG. 2, it will be appreciated that the falling edge of a clock signal could be used instead (with appropriate changes to the other logic, e.g. use of a NOR gate instead of AND gate 202).

The output signal, GEN/N 223, of the generated clock source 203 is also provided to the first AND gate 202 as well as to the ‘clock’ input of a second D flip flop 206, also having its ‘data’ input initially set to be logic high.

Based on the inputs from the reference clock source 201 and the generated clock source 203, the first AND gate 202 outputs an ‘overlap’ signal OL to the ‘data’ input of a third D flip flop 207, which is used to generate an output indicative of the status of the lock detection mechanism 200 (i.e. whether the reference signal REF/M 221 and the generated signal GEN/N 223 at least partially overlap at a given time) as will be described in the following.

In the lock detection mechanism 200, the outputs of the first D flip flop 205 and the second D flip flop 206 are provided to the inputs of a second AND gate 209, as well as to a lead signal detector 211.

The lead signal detector 211 provides an output signal PHASE which is either logic high or logic low depending on whether the generated signal GEN/N 223 leads the reference signal REF/M 221 or vice versa. The PHASE signal may then be provided to an IIR filter and a digital controlled oscillator to adjust the frequency of the generated signal GEN/N 223 to more closely align its phase with that of the reference signal REF/M 221 as described above in relation to the PLL 100 of FIG. 1.

Based on the signals received from the first and second D flip flops 205, 206, the second AND gate 209 is configured to provide a reset signal RST to the reset inputs of the first and second resettable D flip flops 205, 206, as well as to the ‘clock’ input of the third D flip flop 207 (which need not be resettable), used to generate an output indicative of the status of the lock detection mechanism 200.

The signal from the second AND gate 209 is therefore used firstly to reset the first and second D flip flops 205, 206 to output logic low, so as to allow the rising edge of later clock signals to be detected, and is used secondly to trigger sampling of the overlap signal OL from the first AND gate 202, in order to determine whether both the signal GEN/N 223 and the signal REF/M 221 are both in the same state (e.g., both logic high in the embodiment of FIG. 2).

In use, the generated signal GEN/N 223 and reference signal REF/M 221 are provided to the first AND gate 202, as well as to the ‘clock’ inputs of the first and second D flip flops 205, 206. Based on the inputs to the first AND gate 202, the first AND gate 202 outputs a signal to the ‘data’ input to the third D flip flop 207 which is either logic low or logic high. When the edge of a first of the clock signals (e.g. the rising edge of the leading signal) is detected at its respective D flip flop, the D flip flop outputs a logic high signal to the second AND gate 209, as well as to the lead signal detector 211.

At this stage, the second AND gate 209 does not output a logic high signal, as only one of its terminals is receiving a signal which is logic high. However, when the edge of the second of the clock signals (e.g. the rising edge of the lagging signal) is detected at its respective D flip flop, said D flip flop outputs a ‘high’ signal to the AND gate 209 as well as to the lead signal detector 211. Following this, both inputs to the second AND gate 209 are logic high, and the second AND gate 209 outputs a reset signal RST. The reset signal is therefore dependent on both the signal GEN/N 223 and the signal REF/M 221 such that it tracks the lagging edge. In other words, the reset signal is always generated upon receipt of the lagging edge, regardless of which signal is lagging the other. This means that the reset signal is adaptive in the time domain.

The output of the reset signal RST has two effects. Firstly, the outputs of the first D flip flop 205 and the second D flip flop 206 are set to zero, and secondly, the rising edge of the signal from the second AND gate 209 is received at the clock input of the third D flip flop 207. When the third D flip flop 207 detects this transition, it outputs a value set based on the value of its ‘data’ input, i.e. based on the output of the first AND gate 202. This value is dependent on the state of the generated signal GEN/N 223 and the reference signal REF/M 221 at the time the reset signal RST is output. In this way, the lock detection mechanism 200 can determine that the signal GEN/N 223 and the signal REF/M 221 signals are in the same state (e.g. logic high in FIG. 2) as a result of the first D flip flop 205 and the second D flip flop 206 both outputting a logic high signal to the second AND gate 209, and can determine whether the two signals are at least partially overlapping in time (based on the first AND gate 202 outputting a high overlap signal OL). If both of these conditions are met, the third D flip flop 207 provides a logic high signal to the STATUS output 217. If not, the STATUS output 217 is provided with a logic low signal.

The STATUS output 217 may be provided to a counter element (similar to the counter logic 114 of FIG. 1) which can be used to determine the number of clock cycles over which the generated clock signal GEN/N 223 and the reference clock signal REF/M 221 are in the same state (i.e. have overlap). Once a predetermined number of clock cycles has been reached with the signal GEN/N 223 and the signal REF/M 221 in the same state, a digital PLL in which the lock detection mechanism 200 is implemented can be determined to be in the locked condition. Other logic may of course be used to determine a locked state.

Thus, the digital lock detection mechanism 200 may be used to determine whether a first clock signal and a second clock signal are in phase without requiring computationally resource intensive components such as a phase frequency detector. The digital lock detection mechanism 200 also allows the sensitivity of the lock condition to be easily adjusted by changing the duty cycle of the reference clock signal REF/M 221 and/or the generated clock signal GEN/N 223. Thus, the sensitivity may be set by means of the duty cycles. A lower duty cycle results in a lower chance of overlapping signals, and hence a higher sensitivity of the lock condition. By contrast, if a high duty cycle is used, the chance of the reference signal REF/M 221 and the generated signal GEN/N 223 overlapping is higher, decreasing the sensitivity of the lock condition. The simplicity of the arrangement described here is particularly advantageous for allowing this ease of control over the locking sensitivity.

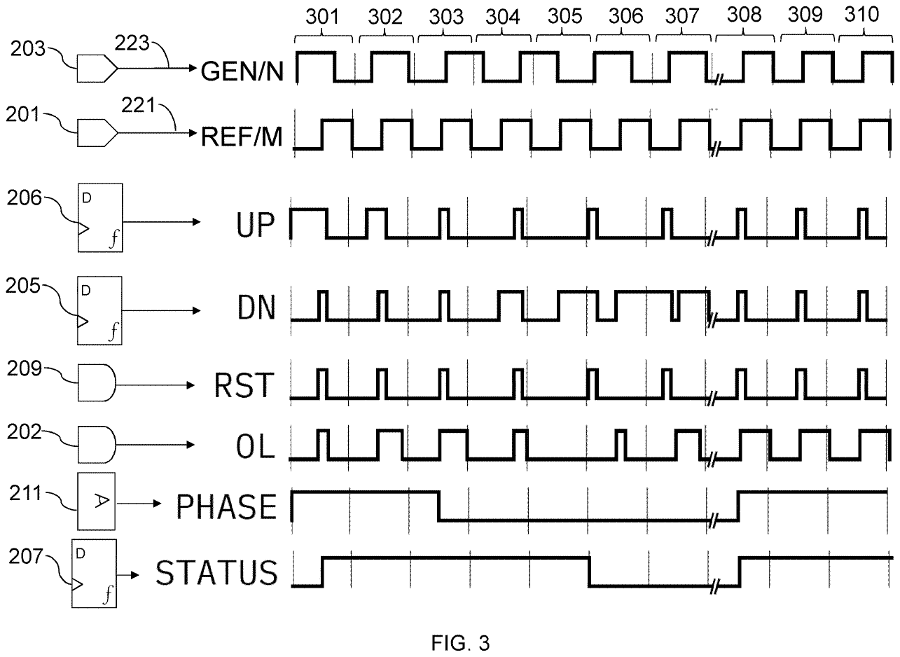

An example of the signals output by the components of the lock detection mechanism 200 in operation is shown in FIG. 3.

FIG. 3 illustrates a time progression of the signals output by the principle components of the lock detection mechanism 200 of FIG. 2 during the process of performing lock detection between the reference signal REF/M 221 received at the reference clock input 201 and the generated signal GEN/N 223 output by the generated clock source 203, between a first time period 301 and a final time period 310. The signals GEN/N 223 and REF/M 221 in FIG. 3 are close in frequency (but not identical). In a first set of time periods 301-307, the generated clock signal GEN/N 223 and the reference clock signal REF/M 221 operate at different frequencies, and in a second set of time periods 308-310 the generated clock signal GEN/N 223 and the reference clock signal REF/M 221 are operating at the same frequency and are coherent.

Initially, in a first time period 301, it can be seen that the generated clock signal GEN/N 223 leads the reference clock signal REF/M 221, i.e. that the leading (left) edge of the pulse in the generated signal is ahead of the corresponding edge of the reference signal.

The pulse in the generated signal GEN/N 223 causes the corresponding output of the second D flip flop 206 (shown in FIG. 3 as ‘UP’) to be logic high, matching that of the generated clock signal.

As the reference clock signal REF/M 221 is logic low during this time period, the output of its corresponding flip flop (first D flip flop 205, shown in FIG. 3 as ‘DOWN’) is also logic low. The first AND gate 202 and the second AND gate 209 (having outputs OL and RST respectively) can also be seen to be logic low, as the generated clock signal GEN/N 223 and the reference clock signal REF/M 221 are in different states. The output of the lead signal detector 211, PHASE, can be seen to be logic high, indicating that the generated signal GEN/N 223 leads the reference signal REF/M 221. The output of the third D flip flop 207, STATUS indicating the status of the lock detection mechanism 200, can be seen to be logic low, indicating that the two signals are not in phase.

However, at the moment the leading edge of the pulse of the reference clock signal REF/M 221 is detected at the first D flip flop 205 (indicated by the start of the pulse in the ‘DOWN’ output of the first flip flop 205 in time period 301), both inputs to the second AND gate 209 become logic high, causing a reset signal RST to be output from the second AND gate 209. Receipt of the reset signal RST at the first D flip flop 205 and the second D flip flop 206 causes their respective output signals DOWN and UP to become logic low for the remainder of the first time period 301.

Receipt of the reset signal RST at the third D flip flop 207 causes the status of the first AND gate 202 to be read at the third D flip flop 207, which provides an output signal STATUS to the status output 217. In the time period 301, at the time the reset signal RST is received at the third D flip flop, both GEN/N 223 and REF/M 221 are logic high, such that the output OL of the first AND gate 202 is also logic high indicating overlap between the two signals. This causes the output signal STATUS of the third D flip flop 207 to transition to the logic high state when the reset signal RST is sent.

In the second time period 302, the generated clock signal GEN/N 223 continues to lead the reference signal REF/M 221, and the process described above repeats.

The leading edge of the pulse in the generated clock signal GEN/N 223 causes the output of the second D flip flop 206 to transition to the logic high state, where it remains until the leading edge of the pulse in the reference signal REF/M 221 causes the output of the first D flip flop 205 to transition to the logic high state. At this time, a reset signal RST is sent to the first D flip flop 205, the second D flip flop 206 and the third D flip flop 207. This causes the first flip flop 205 and the second flip flop 206 to transition to the logic low state, and causes the status of the first AND gate 202 to be read and output by the third D flip flop 207 in the form of the STATUS signal, provided to the status output 217. When the reset pulse RST is sent in time period 302, GEN/N 223 and REF/M 221 are both logic high, and hence the STATUS output remains logic high at this time. The PHASE output 213 also remains logic high as the generated clock signal GEN/N 223 continues to lead the reference clock signal REF/N 221 in the time period 302.

In the time period 303 however, the reference clock signal REF/M 221 ‘overtakes’ the generated clock signal GEN/N 223, becoming the leading signal of the two.

Thus, unlike in time periods 301 and 302, the leading edge of the pulse in the reference clock signal causes the output of the first D flip flop 205 to transition to the logic high state before the second D flip flop 206. A short time later, the leading edge of the pulse in the generated clock signal GEN/N 223 causes the output of the second D flip flop 206 to transition to the logic high state, causing a reset signal to be output by the second AND gate 209. This causes the first D flip flop 205 and the second D flip flop 206 to transition to the logic low state, and causes the status of the first AND gate 202 to be read and output at the STATUS output 217. As in time periods 301 and 302, at the time the reset pulse is sent in time period 303, GEN/N 223 and REF/M 221 are both logic high, and hence the STATUS output remains logic high in the time period 303.

However, the PHASE output 213 transitions to the logic low state as the generated signal GEN/N 223 no longer leads the reference signal REF/M 221 in the time period 303. This process repeats in time periods 304 and 305, in which the reference signal REF/M 221 continues to lead the generated signal GEN/N 223, and the two signals remain aligned in phase.

However, in the example shown in FIG. 3, the STATUS output can be seen to change from logic high to logic low in time period 306. This occurs as, at the time the reset signal RST is triggered at the start of time period 306, the generated clock signal GEN/N 223 is logic high while the reference clock signal REF/M 221 is logic low, i.e. they do not overlap. The signal OL output from the first AND gate 202 is therefore logic low when the reset signal RST is received at the third D flip flop 207, causing the STATUS output for the time period 306 to transition to logic low, where it remains for time period 307.

In time periods 308-310 the generated signal GEN/N 223 and the reference signal REF/N 221 can be seen to be operating at the same frequency and are coherent. In this set of time periods, the first D flip flop 205 and the second D flip flop 206 switch states almost simultaneously, and the output from the first AND gate 202 is consistently logic high at the time the reset signal RST is sent from the second AND gate 209. As such, the STATUS output will remain high while the reference clock signal REF/M 221 and the generated clock signal GEN/N 223 are in phase.

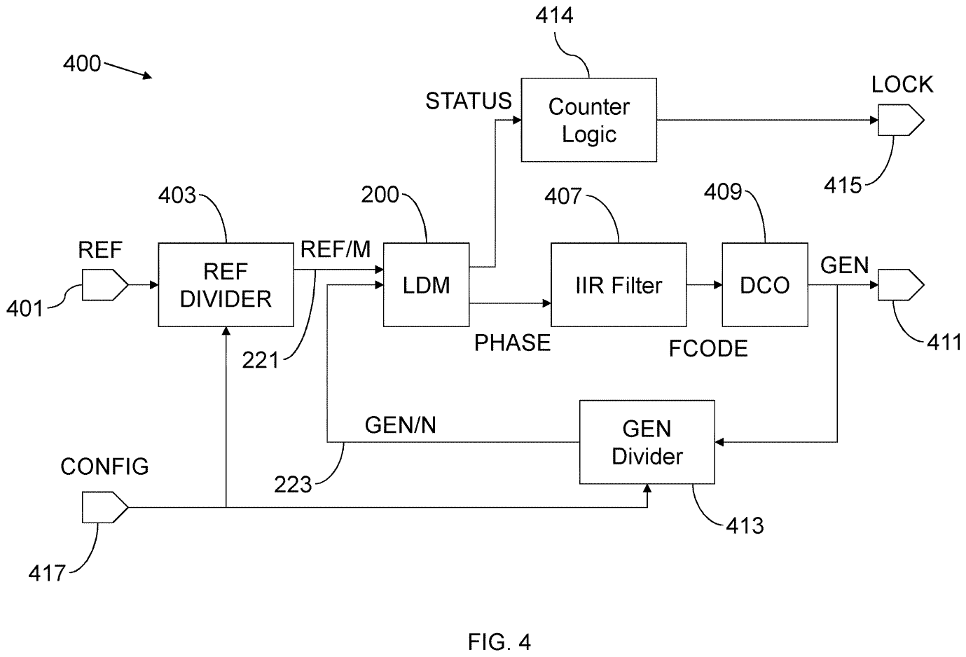

The process outlined above may be incorporated as part of a phase locked loop, as illustrated in FIG. 4. FIG. 4 shows a phase locked loop 400, comprising equivalent components to the phase locked loop 100 shown in FIG. 1, but with the phase frequency detector 107 replaced by the lock detection mechanism 200 of the present disclosure. In the phase locked loop 400 shown in FIG. 4, like components are given corresponding reference numerals to those of the phase locked loop 100 of FIG. 1.

The lock detection mechanism 200 shown in FIG. 4 provides two outputs as described above-a first output in the form of the STATUS signal, provided to counter logic 414, and a second output in the form of the PHASE signal, provided to the IIR filter 407 and the DCO 409, used to bring the generated clock signal GEN closer in phase to the reference clock signal REF. As can be seen in FIG. 4, the implementation shown here uses a REF divider 403 and GEN divider 413 to provide inputs at the lock detection mechanism 200 that are the same frequency.

When the lock detection mechanism 200 is implemented in the phase locked loop 400, the STATUS output is used by the counter logic 414 to determine whether the phase locked loop 400 is in the locked condition.

The counter logic 414 is used to determine whether the STATUS signal remains logic high for a threshold time interval, e.g. for a predetermined number of counts or clock cycles. If such a condition is met, a determination may be made that the reference signal REF and the generated signal GEN are phased locked. As noted above, the strictness of the locking condition can be dynamically adjusted to be more or less severe by adjusting the duty cycles of the divided reference signal REF/M 221 and the divided generated signal GEN/N 223. This duty cycle adjustment may in some embodiments be done by the clock dividers 403, 413 and may thus be adjusted by an appropriate configuration signal 417, e.g. from a controller (not shown).

It will be appreciated by those skilled in the art that the invention has been illustrated by describing one or more specific embodiments thereof, but is not limited to these embodiments; many variations and modifications are possible, within the scope of the accompanying claims.

1. A system for determining whether a first clock signal and a second clock signal are in phase; the system comprising:
a first latch, arranged to receive the first clock signal;
a second latch, arranged to receive the second clock signal;
a first detector; and
a second detector, arranged to receive the first clock signal and the second clock signal;
wherein the first latch is arranged to latch when the first clock signal transitions from a first state to a second state;
wherein the second latch is arranged to latch when the second clock signal transitions from a first state to a second state;
wherein the first detector is configured to output a first detector output signal when the first latch and the second latch are latched; and
wherein the second detector is arranged to generate a second detector output signal upon receiving the first detector output signal, the second detector output signal being indicative of whether both the first clock signal and the second clock signal are in the second state.

2. The system of claim 1, wherein the first detector output signal is received by the first latch and the second latch, causing the first latch and the second latch to reset.

3. The system of claim 2, wherein the first latch and the second latch are bi-stable such that they may be latched or unlatched, and wherein resetting the first latch and the second latch causes the first latch and the second latch to become unlatched.

4. The system of claim 1, wherein the first latch comprises a first resettable D flip flop, wherein the second latch comprises a second resettable D flip flop, and wherein the first resettable D flip flop and the second resettable D flip flop each comprise a respective clocking input and a reset input.

5. The system of claim 4, wherein the first clock signal is provided to the clocking input to the first resettable D flip flop, and wherein the second clock signal is provided to the clocking input to the second resettable D flip flop.

6. The system of claim 4, wherein the reset input of the first resettable D flip flop and the reset input of the second resettable D flip flop are configured to receive the first detector output signal.

7. The system of claim 1, wherein the first latch is configured to detect the change of state of the first clock signal based on the first clock signal transitioning from the first state to the second state and wherein the second latch is configured to detect the change of state of the second clock signal based on the second clock signal transitioning from the first state to the second state.

8. The system of claim 1, wherein the first clock signal and the second clock signal are square waves.

9. The system of claim 1, wherein the first detector is a first logic gate, wherein optionally the logic gate is a first AND gate.

10. The system of claim 1, wherein the second detector is arranged to receive the first clock signal and the second clock signal, and to determine whether the first clock signal and the second clock signal are in the same state.

11. The system of claim 1, wherein the second detector comprises a second logic gate and a third latch.

12. The system of claim 11, wherein the second logic gate is a second AND gate configured to receive, as inputs, the first clock signal and the second clock signal, and to output an overlap signal to the third latch indicative of whether both the first clock signal and the second clock signal are in the same state.

13. The system of claim 12, wherein the third latch is a D flip flop comprising a clocking input and a data input.

14. The system of claim 13, wherein the first detector output signal is provided to the clocking input of the third latch, and wherein the output signal of the second AND gate is provided to the data input of the third latch.

15. The system of claim 1, further comprising a lead signal detector, configured to determine the latching order of the first latch and the second latch.

16. The system of claim 15, wherein the lead signal detector is configured to output an order signal having a first state and a second state; wherein the first state of the order signal indicates that the first clock signal leads the second signal, and wherein the second order state indicates that the second clock signal leads the first clock signal.

17. A phase locked loop comprising the system of claim 1.

18. The phase locked loop of claim 17, comprising a counter element, configured to receive the second detector output signal.

19. The phase locked loop of claim 18, wherein the counter element is configured to determine, based on the second detector output signal, whether the phase locked loop is in a locked state.

20. The phase locked loop of claim 19, wherein the phase locked loop is determined to be in a locked state if the second detector output signal received by the counter element remains constant for a predetermined number of clock cycles.

21. A method of determining whether a first clock signal and a second clock signal are in phase; the method comprising:
detecting a change of state of a first one of the first and second clock signals at a first time,
detecting a change of state of a second one of the first and second clock signals at a second time,
in response to detecting the change of state of the second one of the first and second clock signals at the second time, comparing the state of the first and second clock signals at the second time; and
determining that the first and second clock signals are in phase based on the first and second clock signals being in the same state at the second time.
